(19) United States
(12) Patent Application Publication
(10) Pub. No.: US 2026/0261220 A1
(43) Pub. Date: Sep. 3, 2026

(54) METHOD FOR DIAGNOSING THE STATE OF AN ELECTRIC MOTOR

(71) Applicant: Siemens Aktiengesellschaft, München (DE)

(72) Inventors: Klaus Behringer, Igensdorf (DE); Daniel Pirstat, Amberg (DE); Jürgen Zettner, Veitsbronn (DE)

(21) Appl. No.: 19/163,518

(22) PCT Filed: Jan. 8, 2024
(86) PCT No.: PCT/EP2024/050287

§ 371 Date: Sep. 9, 2025

(30) Foreign Application Priority Data
Mar. 9, 2023 (DE) 10 2023 202 112.9

(51) Int. Cl. H02P 21/14; H02P 21/00

(52) U.S. Cl. CPC H02P 21/14; H02P 21/0014; H02P 2205/01; H02P 2207/01

(57) ABSTRACT

A method for diagnosing the state of an electric motor to which an AC feed voltage with a supply frequency is applied. The method includes the following steps: a) detecting a time series of current values of a machine current which flows through the electric motor as a result of the feed voltage applied to the electric motor; b) describing the time series using an autoregressive model (formula I) of order p; c) forming a feature vector with p vector elements, wherein the p vector elements are formed by the p parameters ai of the autoregressive model; and d) using the formed feature vector in an ML algorithm as training data or as test data.

### METHOD FOR DIAGNOSING THE STATE OF AN ELECTRIC MOTOR

The present invention relates to a method for diagnosing the state of an electric motor.

One known method for diagnosing the state of an electric motor is what is known as motor current signature analysis (MCSA); see for example EP3961230A1 (Siemens AG) 02.03.2022 and Kumar, K. Vinoth et al.: A Review of Voltage and Current Signature Diagnosis in Industrial Drives. International Journal of Power Electronics and Drive Systems (IJPEDS) Volume 1, Number 1, September 2011, pages 75-82, ISSN 2088-8694. The basis of MCSA is that of recording the electrical phases, usually three (L1, L2, L3), of an electric motor. The recorded measured values are then analyzed: a frequency spectrum is usually generated from the measured timeseries with the aid of a fast Fourier transformation (FFT). MCSA involves looking at changes in the amplitudes of characteristic frequencies in the frequency spectrum in order to detect and quantify faults and operating states of the electric motor in the frequency domain.

The use of FFT brings up a conflict between frequency resolution and recording duration: On the one hand, a high frequency resolution is desirable in order to be able to identify motor faults unambiguously. On the other hand, precisely this process requires a relatively long recording duration in an operating state that is as constant as possible, that is to say a large amount of measurement data. Firstly, however, a quasi-stationary operating state over a relatively long duration is unrealistic; secondly, handling large amounts of data is burdensome.

One object of the present invention is therefore an improved method for monitoring the state of an electrical machine.

According to the invention, this object is achieved by a method having the features specified in claim 1.

This is a method for diagnosing the state of an electric motor. In this case, an AC supply voltage having a supply frequency is applied to the electric motor (AC=alternating current). In a first step, a timeseries of current values of a machine current flowing through the electric motor on account of the supply voltage applied to the electric motor is recorded. In this case, the machine current flowing through wire coils of the electric motor generates a magnetic field that, in interaction with a second magnetic field (permanent magnet or electromagnet), leads to rotation of a rotor of the electric motor. In a following step, the recorded timeseries is described with a p-th order autoregression model

$${y}_{t} = c + {ε}_{t} + {\sum }_{i = 1}^{p} {a}_{i} {y}_{t - i} :$$

The constant c, the noise term εₜ and the p parameters aᵢ, which may be designated as weighting coefficients, are ascertained, these being used to compose a value yₜ of the timeseries from the p preceding values yₜ₋ᵢ of the timeseries, with i=1, . . . , p. In a following step, a feature vector with p vector elements is formed, wherein the p vector elements are formed by the ascertained p parameters aᵢ of the autoregression model. In a following step, the formed feature vector is used in an ML algorithm as training data or as test data (ML=machine learning).

In the state diagnosis method, the following phases may be run through in succession:
a training phase
   a1 recording phase (generating feature vectors of the “good state”)
   a2 learning phase (teaching the “good state” of the electric motor)
b test phase (state monitoring)

The invention is based on the finding that it is possible, using autoregression, from time values of a timeseries, to “condense” the information relevant for anomaly detection to a few values, such that interfering information is omitted, important information is retained and the amount of data to be processed is significantly reduced.

The present invention provides a method for diagnosing the state of an electric motor on the basis of machine learning or artificial intelligence (AI). The input values required for the AI, known as features, are obtained here from the current samples with the aid of an AR model.

A p-th order autoregression model, denoted: AR(p), may be written as:

$${y}_{t} = c + {ε}_{t} + {\sum }_{i = 1}^{p} {a}_{i} {y}_{t - i}$$

The signal yₜ is composed of a constant c, a noise term Et and a weighted, moving average of the p preceding signal values yₜ₋ᵢ, wherein the AR parameters aᵢ, with i=1, . . . , p, are the weights (AR=autoregression). In the context of the present invention, what is of interest is not the 24 signal yₜ itself, however, but rather the issue as to how the AR algorithm “models” the signal yₜ. In this case, the most important input value, other than the signal values yₜ₋ᵢ, is the lag or the order. The lag is the number of periods p that the AR model uses to ascertain the signal yₜ. If a 1st-order autoregressive model=AR(1):

$${y}_{t} = c + {ε}_{t} + {a}_{1} {y}_{t - 1}$$

has only a single lag value yₜ₋₁, then a 2nd-order autoregressive model=AR(2):

$${y}_{t} = c + {ε}_{t} + {a}_{1} {y}_{t - 1} + {a}_{2} {y}_{t - 2}$$

already has two lag values yₜ₋₁ and yₜ₋₂. pth-order autoregressive models accordingly then have p lag values.

AR models are normally used, in the case of discrete timeseries y(t), also written yₜ, to analyze systematic past relationships or to make predictions for the future. However, it turns out that an autoregression model is also very suitable for supplying the features for an ML algorithm.

According to the invention, the parameters aj ascertained by the AR model form the vector elements of a feature vector that represents the key information of the input signal, that is to say the timeseries. In principle, it would also be possible to use the timeseries itself, that is to say the samples yₜ of the current, as features, but this entails problems, as explained in following points a) and b):

a) Very large feature vectors: Typical sampling frequencies of 2000 to 20,000 sps (samples per second) give rise, in the case of a recording duration of approx. 1 second, to feature vectors with 2000 to 20,000 values, that is to say having a size that is burdensome to handle.

b) Quantity: The current values depend, in terms of quantity, on the load, that is to say a higher motor current flows at higher loads. However, a state diagnosis method is not supposed to classify a change in load as an anomaly, but rather only an anomaly of the motor.

The invention circumvents the abovementioned disadvantage of large amounts of data, wherein 2000 to 20,000 measured current values form a feature vector, by compressing the data using an AR model; such compression makes sense because the information content of a single measured current value is relatively small and it is readily possible to increase entropy through autoregression.

In contrast to conventional MCSA, the present invention does not use spectral components, that is to say values in the frequency domain, but measured current values, that is to say values in the time domain. According to the invention, no physical models are used either, rather the method works exclusively “generically” with machine-learning or artificial intelligence (AI) methods.

A further advantage of the method according to the invention is that the problem of “data quality”, which is important for ML, is thereby solved. In spectral analysis, a large number of features (frequency lines) represent only “noise”. On the one hand, these may be static elements, that is to say they do not have any “useful” information for the system; on the other hand, these “noise” features may lead to completely incorrect models during learning, because these features are values other than 0. It is very difficult to filter out these “noise components” in advance, because a threshold for the filter would have to be known, on the one hand, and the frequencies vary depending on the load state, on the other hand.

As an alternative to the “standard” autoregression methods, it is also possible to use modified AR methods such as autoregressive moving average (ARMA), autoregressive moving average with exogenous inputs (ARMAX) and autoregressive integrated moving average (ARIMA).

A feature vector generated according to the invention May be used for various AI and ML methods, both for supervised learning methods, for example classification and regression algorithms, and for unsupervised learning methods. 9

Advantageous embodiments and developments of the invention are specified in the dependent claims.

According to one preferred embodiment of the invention, said electric motor is an asynchronous motor. On account of their cost-effective and robust design, asynchronous motors (ASM) are very widespread in industry: they may be found in many applications such as for example fans, saws and pumps, from relatively small systems in the watts range up to systems in the MW range. Asynchronous motors therefore belong to the largest consumers of the electrical energy that is generated worldwide. Owing to the wide spread of asynchronous motors, the result is an enormous potential with regard to availability and reliability and the associated saving in time and money.

According to one preferred embodiment of the invention, the timeseries of current values is recorded in phase-locked fashion, that is to say current values are sampled in synchronicity with the grid frequency, resulting in a constant phase. The measured current values are thus always recorded (“sampled”) at times when the current signal has predefined phases, for example 64 samples per full wave of AC current. This phase-locked sampling makes it possible to significantly improve the state diagnosis method. The phase-locked sampling may be carried out here, on the one hand, with the aid of hardware in the form of a phase-locked loop (PLL). The sampling frequency in this case always also adapts to the grid frequency, that is to say the “start phase” is always constant. As an alternative, the measured current values may first be sampled at a fixed sampling frequency. In a subsequent step, a “soft PLL”, that is to say a PLL implemented by software or firmware, is applied to the measured current values. Interpolating the values gives rise to calculation of a sampling grid in a form that results in a fixed “starting phase”, and the sampling frequency is a constant multiple of the grid frequency.

According to one preferred embodiment of the invention, the method furthermore comprises the following steps: At least one first feature vector is used as training data for the ML algorithm. At least one second feature vector is used as test data for the ML algorithm. A diagnosis of a state (“state diagnosis”) of the electric motor, which is documented in the form of the second feature vector (test data), is made with the aid of the ML algorithm based on a comparison of the at least one second feature vector (test data) with the at least one first feature vector (training data). This embodiment concerns state monitoring based on an unsupervised learning method. In this case, an electric motor, in a first part of a training phase, referred to as a recording phase, is operated for a limited time in a “good state”, that is to say in fault-free operation, wherein, during this time, measured values, for example measured values of the current strength of the current flowing through the motor windings, are recorded and, according to the invention, feature vectors that describe this “good state” are generated therefrom. In a second part of the training phase, referred to as a learning phase, an ML algorithm is trained with a plurality of these feature vectors, that is to say the ML algorithm sees only the “good state” of the electric motor, but does not know the “bad state”, that is to say faulty operation, of the 6 electric motor. After the training phase has finished, a test phase, also called a detection phase, of the ML algorithm is activated, that is to say, from this point on, the ML algorithm monitors the electric motor for operating states that deviate from the taught “good state” of the electric motor, referred to as “anomalies”, and reports them to an operator. In detail, the following phases are thus run through in succession:
a training phase
   a1 recording phase (generating feature vectors of the “good state”)
   a2 learning phase (teaching the “good state” of the electric motor)
b test phase (state monitoring)

A supervised learning method has the disadvantage, compared to an unsupervised learning method, that “good” and “bad” data have to be trained. This is usually not possible in a customer system. If training has to be carried out at the manufacturer, then a large number of models has to be supplied. In “unsupervised” learning, on the other hand, the system is trained only with “good” data; after training, the system recognizes “bad” data as an “anomaly”.

According to one preferred embodiment of the invention, the method comprises the following three steps: it comprises the first step whereby the phase angle at the start of the timeseries is recorded for the at least one first feature vector, which is used as training data. For each timeseries of current values, the phase angle at the start of the timeseries, referred to as the “start phase”, is thus recorded. The respective start phase is recorded for all timeseries in the training phase, and all recorded start phases are documented, for example stored as an entry in a list or in a file. The method furthermore comprises the second step whereby the phase angle at the start of the timeseries is recorded for at least one second feature vector, which is to be used as test data. The start phase is thus likewise ascertained from the recorded timeseries in the test phase following the training phase. The method furthermore comprises the third step whereby the at least one second feature vector is used as test data for the ML algorithm only if the phase angle assigned to the second feature vector at the start of the timeseries matches a phase angle assigned to a first feature vector at the start of the timeseries. Only those timeseries for which an entry having the same start phase is available in the training phase are thus evaluated; two phases are considered to be the same here if they match within a specified tolerance. Only timeseries having a “known” start phase are thus evaluated in the test phase.

According to one preferred embodiment of the invention, the data are “internally normalized”, that is to say the phase position and amplitude of the signal are automatically adjusted by the algorithm; this means that no effort is incurred for the user. The time domain values of the current I are preferably normalized to a maximum value of the absolute value of the current before the AR calculation, that is to say a normalized measured current value Iₙₒᵣₘ=I/(max(abs(I)) is calculated from a measured current value I that is measured. This makes the features independent of the signal amplitude. Through this normalization of the current values, the invention circumvents the abovementioned disadvantage of the quantitative dependency of the current values on the load.

According to one preferred embodiment of the invention, in addition to the parameters aᵢ of the AR model, information criteria are also calculated, for example the Akaike information criterion (AIC). The Akaike information criterion states that a model should not be unnecessarily complex and should strike a balance between maximum fit quality and minimum complexity of the model. The fit quality is a measure of how well the model replicates the real data, for example measured by the residual sum of squares. The complexity of the model may be measured for example by the number of model parameters. Since the p parameters aᵢ of the AR model are used as vector elements of a feature vector for the ML algorithm, the lag determines the size of the feature vector. An information criterion may be used to estimate whether the lag size has been selected appropriately (too large, too small, optimal); the lag size may be optimized based on an information criterion.

According to one preferred embodiment of the invention, the feature vector is used for state monitoring with the aid of a self-organizing map (SOM).

The idea of a SOM is to create a grid of X*Y neurons N. Each neuron N in this case contains a weight vector of length L_{F}, that is to say equal to the length of a feature vector. In this case, determining the number of neurons (X *Y) is a compromise between the amount of data/computational outlay, on the one hand, and the desired reliability of an anomaly detector, on the other hand. In tests already carried out, 20×20=400 neurons produced very good results.

Like most artificial neural networks, self-organizing maps work in two modes: training and mapping. In training mode, an input dataset (input space) is used to generate a map as a lower-dimensional representation of the input data (map space). In mapping mode, measured data are classified, for example as normal or abnormal, using the generated map.

Teaching the SOM, that is to say training, is an iterative process. In the initial state, the weight vectors contain random values. The learning process then takes place such that similar feature vectors from the training dataset are assigned to the same neuron. In this context, “similar” should be understood in the sense of a vectorial distance, that is to say use may be made of for example the Euclidean distance, the cosine distance, or the Manhattan distance, depending on the application.

The aim of the training is to represent a p-dimensional input space, that is to say with p variables, as a 2-dimensional map space. A map space consists of components called nodes or neurons, which are arranged on a hexagonal or rectangular two-dimensional grid. The number of nodes and their position on the grid are determined in advance, based on the aim pursued by the analysis and examination of the input space.

Each node of the map space is assigned a weight vector that defines the position of the node in the input space. While the nodes remain anchored at their position in the map space, the weight vectors are made to approximate the input data, that is to say the distance, for example the Euclidean distance, between the weight vector and the input data is minimized without destroying the topology generated by the map space.

During the training phase, feature vectors that are “similar” to one another are grouped together. Here, this similarity is defined as the Euclidean distance, that is to say the smaller the distance between the feature vectors, the more similar the feature vectors are. One or more representatives are chosen for each “group” of similar feature vectors, as is the maximum distance Dmax for each group.

Once the training phase has been completed, the SOM generated in this way may be used to classify further input space vectors, that is to say observations in the input space, timeseries of current values in the present case, by identifying the nodes whose weight vector is closest to the input space vector, that is to say has the smallest distance metric, for example Euclidean distance.

A feature vector generated according to the invention with p vector elements, which were obtained by way of an AR method from a timeseries measured on an electric motor, is assigned to a neuron of said SOM and a weight vector assigned to the neuron.

To be able to use the trained SOM as an anomaly detector, there is a need for a function that assigns a feature vector Fν a degree to which the feature vector represents an anomaly. For this purpose, the “quantization error” Eν is calculated for each feature vector Fν:

$$Ev = \vert Fv - Gv \vert$$

for all values of v, that is to say for all feature vectors. Here . . . is the previously defined vectorial distance and Gv is the respective weight vector of the “optimal” neuron, that is to say the neuron whose weight vector G has the minimum distance from the feature vector. The quantization error E describes how well the respective feature vector is able to be mapped onto the distribution of the data used to train the SOM. A high error in this case indicates that the feature vector is very different from the training data, and therefore describes an abnormal behavior of the motor. In practice, an anomaly of the electric motor is ascertained if the quantization error Ex exceeds a fixedly predefined threshold value E_{Threshold}: EX>E_{Threshold}.

After training, anomaly detection is carried out as follows:

A feature vector is generated from the input values, as described above. The Euclidean distance from the learnt “groups” is determined for this vector. The minimum value of all distances is determined. An anomaly is present if this value is greater than Dmax.

The invention is explained below with reference to the accompanying drawing. In each case, schematically and not to scale,

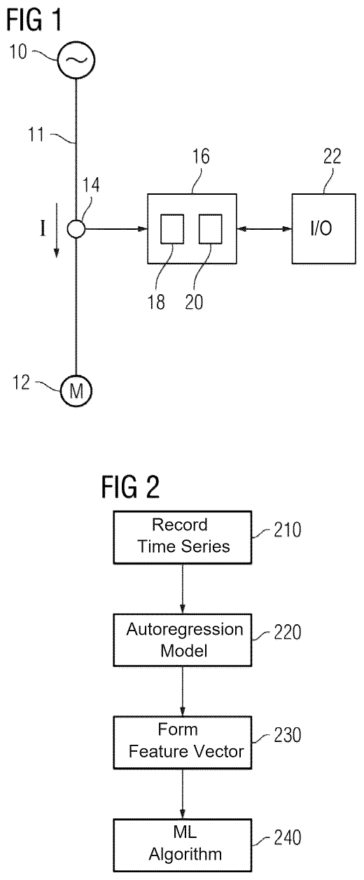

FIG. 1 shows one embodiment of a drivetrain comprising an electric motor;

FIG. 2 shows a flowchart of one embodiment of the method according to the invention;

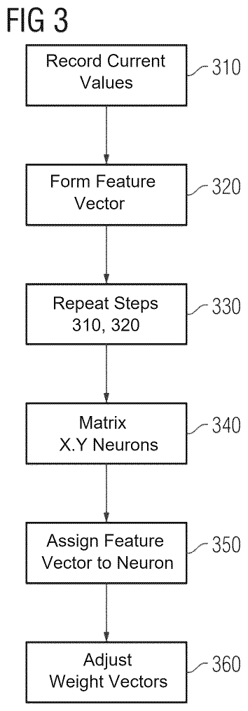

FIG. 3 shows a flowchart of another embodiment of the method according to the invention; and

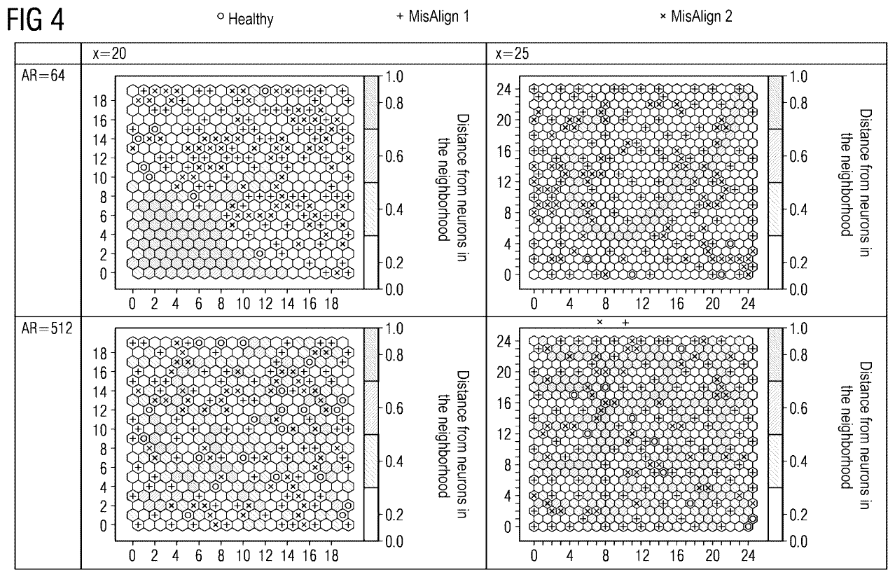

FIG. 4 shows one embodiment of a SOM.

FIG. 1 shows an arrangement comprising an asynchronous motor 12, which is electrically conductively connected via supply lines 11 to an AC voltage source 10, which supplies a supply voltage U_{supply} having a voltage frequency f_{supply}. The current I flowing through the supply lines 11 is measured by a current sensor 14, for example a shunt, a current converter or a Hall sensor. Measured current values are each recorded at the sampling frequency f_{A} [1/T] for a measurement duration T_{A} [T]. The number of samples N_{A} is thus N_{A}=f_{A}*T_{A}. For example, f_{A}=3200 Hz, and T_{A}=1.28 seconds, and therefore N_{A}=4096=212 samples. At a voltage frequency f_{supply}=50 Hz signal, 3200/50=64 samples are recorded per AC oscillation, that is to say 32 samples per AC half-oscillation. The N_{A} measured current values recorded by the current sensor 14 are transmitted from the current sensor 14 to a computing unit 16. A respective feature vector is formed from these N_{A} measured current values by the computing unit. Lag=64 is selected as the minimum lag. This already achieves very good results. This means that the key information of the time signal may already be represented using 64 (instead of 4096) values. Lag=512 is used as the maximum lag.

The method steps for ascertaining the feature vectors are carried out by the computing unit 16. To this end, the computing unit 16 has a processor 18 and a data memory 20. The data memory 20 stores software comprising an algorithm for forming a feature vector from the measured current values. This software is executed by the processor 18. Input values, such as the measurement duration T_{A}, may be transferred to the computing unit 16 by an input/output unit 22, for example a PC, connected to the computing unit.

After detection of an anomaly, the computing unit 16 sends a corresponding message to the input/output unit 22. 2 FIG. 2 shows a flowchart of one embodiment of the method according to the invention for diagnosing the state of an electric motor M to which a supply voltage U having a supply frequency is applied.

In a first step 210, a timeseries It of current values of a machine current I flowing through the electric motor M on account of the supply voltage U applied to the electric motor M is recorded.

In a second step 220, the timeseries It is described by a p-th order autoregression model

$${y}_{t} = c + {ε}_{t} + {\sum }_{i = 1}^{p} {a}_{i} {y}_{t - i} .$$

In a third step 230, a feature vector Fₓ with p vector elements is formed, wherein the p vector elements are formed by the p parameters aᵢ of the autoregression model.

In a fourth step 240, the formed feature vector Fₓ is used in an ML algorithm as training data or as test data.

The recording phase is followed by the learning phase. During this phase, the recorded feature vectors, labeled with a slip label Lₛ, are taught into a SOM.

A description is given, by way of example, of how the features form the basis for an anomaly detector. The goal here is unsupervised learning, that is to say the system is trained only with “good” data, and should recognize “bad” data as an “anomaly” after training.

During the training phase, feature vectors that are “similar” to one another are grouped together. This similarity is defined as follows here: Each feature is understood to be a vector of length L. The similarity is defined here as the Euclidean distance, that is to say the smaller the distance, the more similar the features are (https://de.wikipedia.org/wiki/Euklidischer Abstand). One or more representatives are chosen for each “group”, as is the maximum distance Dmax for each group.

FIG. 3 shows a flowchart of one embodiment of the method according to the invention for diagnosing the state of an electric motor M to which a supply voltage U having a supply frequency is applied, with the aid of a SOM.

In a first step 310, current values Iₘ of an electric current flowing through the electric motor M are recorded. This thus gives a timeseries It of LF current values Iₘ of a current I flowing through the asynchronous motor M on account of the supply voltage U applied to the asynchronous motor M, while the asynchronous motor M is in a good state. During the recording phase, current values Iₘ that describe the “good state” of the motor are recorded. These current values Iₘ are then used to train the anomaly detector. The following aspects are very important here:

The system should record as many load states or slip values as possible in the slip value range [Sₘᵢₙ, . . . , S_{N}]. For each recording, the respective slip should be carried 23 along as a “label” Lₛ.

If a load state is recorded, then the load state (=slip) must be approximately constant for the duration of the recording T_{A}: Ls=constant. It does not make sense to record the current values in the event of large load changes (=slip changes), because otherwise different states would be overlaid, and thus different frequency spectra would also be overlaid.

The recording phase is terminated when a sufficiently large variation in slip values has been recorded or when the maximum time provided for the recording has been reached.

In a second step 320, a feature vector Fν with p vector elements is formed from the current values It of the recorded timeseries, wherein the p vector elements are formed by the p parameters aᵢ of the autoregression model. This feature vector Fν is assigned a slip value of the slip s of the asynchronous motor.

In a third step 330, steps 310 and 320 are repeated at different slip values so as to obtain a group of feature vectors Fν as a training dataset.

In a fourth step 340, a matrix of X by Y neurons is generated, wherein each of the neurons is assigned a weight vector G of length LF.

In a fifth step 350, a neuron is assigned those feature vectors Fν from the training dataset whose vectorial distance from the neuron does not exceed a specified distance limit value.

In a sixth step 360, the weight vectors G of the neurons are adjusted such that the distance between the weight vector G and the feature vectors Fν assigned to a neuron is minimal.

After training, anomaly detection is carried out as follows:

A feature vector is generated from the input values, as described above. The respective Euclidean distance from the learnt “groups” is determined for this vector. The minimum value of all distances is determined. An anomaly is present if this value is greater than Dmax.

FIG. 4 shows four different SOMs. A SOM is a 2-dimensional visualization spanned by an x-axis and a y-axis.

The idea of a SOM is to create a grid of X*Y neurons N. Each neuron N in this case contains a weight vector whose length is identical to the length of a feature vector. In this case, determining the number of neurons (X*Y) is a compromise between the amount of data/computational outlay, on the one hand, and the desired reliability of the anomaly detector, on the other hand. In tests already carried out, 20×20=400 neurons produced very good results.

A parameter X is plotted on the x-axis and a parameter Y is plotted on the y-axis, wherein X and Y define the size of the SOM map. The product X*Y gives the number of neurons represented as honeycombs in the SOM. The left-hand column, with “X=20”, illustrates two SOM maps with X=Y=0, 19. The right-hand column, with “X=25”, illustrates two SOM maps with X=Y=0, 24. This results in N=20*20=400 n euron honeycombs in the left-hand column and N=25*25=625 n euron honeycombs in the right-hand column. The two columns are divided horizontally into two rows: the upper row, with “AR=64”, shows the SOM maps in which an autoregression AR with lag=64 was used to generate the feature vectors, that is to say 64 feature vector elements per feature vector; the lower row, with “AR=512”, shows the SOM maps in which an autoregression AR with lag=512 was used to generate the feature vectors, that is to say 512 feature vector elements per feature vector. The SOM maps show the unpopulated neuron honeycombs or those populated with “good” or “fault”; “double population” of a neuron honeycomb is also possible here. The darker a neuron honeycomb, the greater the “distance” from the neighboring neuron honeycomb. The optimum situation is when as many neuron honeycombs as possible are populated and there is as far as possible no “double population”.

Teaching the SOM is an iterative process. In the initial state, the weight vectors contain random values. The learning process then takes place such that similar training vectors from the training dataset are assigned to the same neuron. In this context, “similar” should be understood in the sense of a vectorial distance, that is to say use may be made of for example the Euclidean distance, the cosine distance, or the Manhattan distance, depending on the application.

Since the number v of generated feature vectors Fν is generally much greater than the number of neurons, a neuron represents a large number of feature vectors. During training, the weight vector G of each neuron is adjusted such that the distance between the weight vector G and the training vectors assigned to the neuron Fν is minimal. In an optimally trained SOM, training vectors have been assigned to each neuron. The trained SOM then represents a compact representation of the training data distribution.

To be able to use the trained SOM as an anomaly detector, there is a need for a function that assigns a feature vector Fν a degree to which the feature vector represents an anomaly. For this purpose, the “quantization error” Eν is calculated for each feature vector Fν:

$$Ev = \vert Fv - Gv \vert$$

for all values of v, that is to say for all feature vectors. Here |Fν−Gν| is the previously defined vectorial distance and Gν is the respective weight vector of the “optimal” neuron, that is to say the neuron whose weight vector G has the minimum distance from the feature vector. The quantization error E describes how well the respective feature vector is able to be mapped onto the distribution of the data used to train the SOM. A high error in this case indicates that the feature vector is very different from the training data, and therefore describes an abnormal behavior of the motor.

The minimum error

$${E}_{min} = min \{ Ev \}$$

and the maximum error

$${E}_{max} = max \{ Ev \}$$

are then determined over all feature vectors in the training dataset.

During the test phase following the learning phase, in which the device operates as an anomaly detector, the following steps are then carried out, similarly to in the recording phase:

Samples are recorded again for the time T_{A}.

It is checked whether the load state of the motor was “stationary” during this time, that is to say no major load changes were present, and whether the slip was present during this recording in the training phase. A suitable tolerance for the slip may be defined here, since slip is not able to be determined in error-free fashion, or it is necessary to check during the training phase what “slip error” would lead to an “anomaly”.

After a successful check, the feature vector Fₓ is calculated from the samples.

For this feature vector, the SOM supplies the associated neuron and the weight vector Gx corresponding to the neuron.

The quantization error Ex=|Fₓ-Gx is calculated from these values.

The simplest variant of an anomaly detector may be implemented as follows: A fixed threshold value E_{Threshold} iS defined for the quantization error. If this is exceeded, then there is a high probability of an anomaly being present. It is obvious to select E_{Threshold}=Eₘₐₓ, that is to say the maximum quantization error during the training phase is used as threshold value. If the distance between the test vector and the corresponding weight vector thus becomes too large, then an anomaly is present.

However, this simple variant has disadvantages that are to be explained based on results of experiments with real motor data. For this purpose, training is carried out on a fault-free system (motor) with 100 feature vectors (“good”). Different load states are trained here. The test phase involves testing these 100 feature vectors in the “good” state. The system is then intentionally “damaged”, for example the motor is misaligned (“anomaly”). The test is carried out only in load states that have been trained previously. A total of a further 200 feature vectors are tested.

1-5. (canceled)

6. A method of diagnosing a state of an electric motor to which an AC supply voltage having a supply frequency is applied, the method comprising the following steps:
a) recording a timeseries of current values of a machine current flowing through the electric motor on account of the supply voltage applied to the electric motor;
b) describing the timeseries using a p-th order autoregression model
$${y}_{t} = c + {ε}_{t} + {\sum }_{i = 1}^{p} {a}_{i} {y}_{t - i} ;$$
c) forming a feature vector with p vector elements, wherein the p vector elements are formed by p parameters aᵢ of the autoregression model; and
d) using the feature vector in a machine learning (ML) algorithm as training data or as test data.

7. The method according to claim 6, wherein the electric motor is an asynchronous motor.

8. The method according to claim 6, which comprises recording the timeseries in phase-locked fashion.

9. The method according to claim 6, which comprises:
using at least one first feature vector as training data for the ML algorithm;
using at least one second feature vector as test data for the ML algorithm;
making a state diagnosis using the ML algorithm based on a comparison of the at least one first feature vector with the at least one second feature vector.

10. The method according to claim 9, which comprises:
recording the phase angle at a start of the timeseries for the at least one first feature vector, which is used as training data;
recording the phase angle at the start of the timeseries for at least one second feature vector, which is to be used as test data;
using the at least one second feature vector as test data for the ML algorithm only when the phase angle assigned to the second feature vector at the start of the timeseries matches a phase angle assigned to a first feature vector at the start of the timeseries.
